(19) United States
(12) Patent Application Publication
(10) Pub. No.: US 2003/0076661 A1
(43) Pub. Date: Apr. 24, 2003

(54) Electronic elements mounting apparatus

(75) Inventors: Kazuhito Murata, Tokyo (JP); Akira Takeishi, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, Tokyo (JP)

(21) Appl. No.: 10/271,583

(22) Filed: Oct. 17, 2002

(30) Foreign Application Priority Data
Oct. 18, 2001 (JP) 2001-320969
Jan. 28, 2002 (JP) 2002-018488

(51) Int. Cl. H05K 7/02; H05K 7/06; H05K 7/08; H05K 7/10

(52) U.S. Cl. 361/760

(57) ABSTRACT

A bonding apparatus includes a bonding arm which is swayable about an axis, a horn which is fixed at the end of the bonding arm to perform ultrasonic bonding, a tool fixed on the horn, and a motor on the bonding arm at the opposite end to the horn. The bonding head both moves and bonds an electronic element.

### BACKGROUND OF THE INVENTION

1. Field of the Invention

The present invention relates to an apparatus for mounting electronic elements on a substrate. More particularly, it relates to an apparatus for high-speed handling and mounting the electronic elements.

2. Description of Related Arts

In a conventional apparatus for mounting electronic elements, several tools are operated sequentially. For example, one tool moves an electronic element to a substrate placed on a bonding stage and then another tool bonds the element on the substrate. In other words, the electronic elements are moved and bonded by different tools.

FIG. 3 is a side view of a conventional bonding head. The bonding head 10 is used to bond an electronic element 50, which is moved by another tool (not shown) to a substrate 51. The bonding head 10 comprises a bonding arm 12 fixed to a guide structure 20, a horn 13 installed on an end of the bonding arm 12, a tool 14 installed on an end of the horn 13, and a linear motor 30 provided on the bonding arm 12 at the opposite end to the horn 13. The bonding head 10 moves along a guideway 21 on an X-Y stage 1 by operation of the linear motor 30. The horn 13 oscillates ultrasonically to cause tool 14 to bond the electronic element 50 to substrate 51. The linear motor 30 has a coil 31 and a magnet 32 that surrounds the coil 31.

As described above, the conventional mounting apparatus has at least two different tools which respectively and sequentially move an electronic element to a substrate and bond the electronic element to the substrate. The use of two tools increases cost and prevents high speed operation.

### SUMMARY OF THE INVENTION

An object of the present invention is to provide a high-speed bonding apparatus that moves and bonds electronic elements with the same tool.

To solve the above-mentioned problem, the apparatus of this invention has a bonding arm that can ultrasonically bond the electronic element in the conventional manner and that includes a suction apparatus for moving the electronic element.

### BRIEF DESCRIPTION OF THE DRAWINGS

The above and other objects, features and advantages of the present invention will become more apparent from the following detailed description when taken in conjunction with the accompanying drawings wherein:

FIG. 1 is a side view of a first embodiment of a bonding head of the present invention.

FIG. 2 is a side view of a second embodiment of a bonding head of the present invention.

FIG. 3 is a side view of a conventional bonding head.

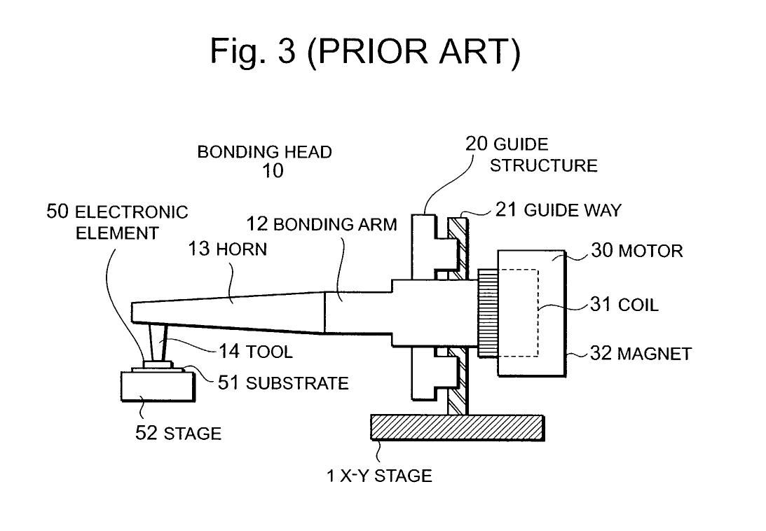

### DETAILED DESCRIPTION OF THE PREFERRED EMBODIMENTS

Embodiments of the present invention will now be described in detail below with reference to the accompanying drawings.

The bonding head 10 holds an electronic element 50 using a tool 24 and brings it to a predetermined position on a substrate 51 placed on a stage 52. A bonding head has a pipe 15 connected to a vacuum or other low pressure source 53 to hold an electronic element at the tip of the tool 24 with suction. After the above-mentioned steps, the bonding head 10 bonds the electronic element on the substrate using ultrasonic waves generated by the horn 13.

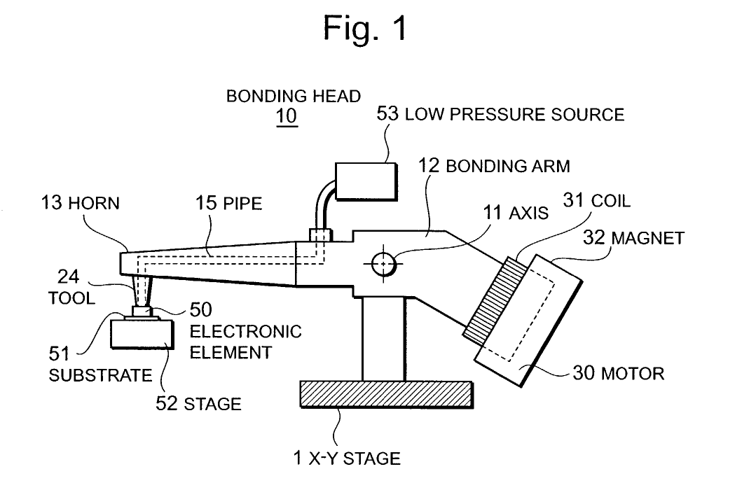

FIG. 1 is a side view of a bonding head of a first embodiment of this invention. The bonding head 10 comprises a bonding arm 12 movable about an axis 11 and located on the X-Y stage 1, a horn 13 on an end of the bonding arm 12, a tool 24 on an end of the horn 13, and a motor 30 on the bonding arm 12 at the opposite end to the horn 13. The motor 30 is formed by a coil 31 and a magnet 32 provided so as to surround the coil portion 31. The horn 13 may be provided with an oscillator or can otherwise be made to oscillate for generating ultrasonic waves in the tool 24.

In operation, the bonding head 10 holds an electronic element 50 at the tip of the tool 24 with suction and moves the element to a predetermined position on a substrate 51.

The motor 30 generates a force to move the bonding arm 12 about the axis 11. Thereby, the tool 24 moves substantially vertically to the stage 52 and mounts the electronic element 50 on the substrate 51.

After mounting the electronic element, the horn 13 generates ultrasonic waves to bond the element to the substrate.

As a result, the moving and bonding of the electronic element 50 can be performed by the same bonding head 10.

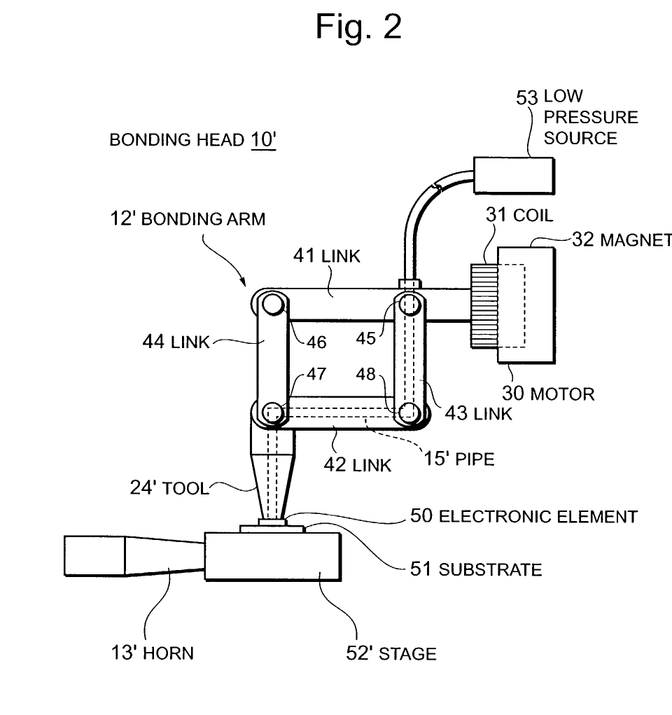

FIG. 2 is a side view of a second embodiment of this invention.

As shown in FIG. 2, a bonding head 10′ of this embodiment comprises plural links and rotating joints instead of the bonding arm described in the first embodiment. Furthermore, in this embodiment, a horn 13′ is provided with the stage.

The plural links and rotating joints (link mechanism) includes a link 41, links 43 and 44 connected to the link 41 via rotating joints 45 and 46 respectively, and a link 42 connected to the links 43 and 44 via rotating joints 47 and 48 respectively. That is to say, a parallel link mechanism composed of four links and four rotating joints is formed. The bonding head 10′ has a tool 24′ at a rotating joint 47. The stage 52′ is provided with a horn 13′ for generating ultrasonic waves. A suitable connection 15′ to low pressure source 53 (FIG. 1) is provided through links and joints 41-48. A motor 30 is connected to the rear end of the link 41. This motor 30 has a coil 31 installed at the rear end of the link 41 and a magnet 32 provided on the support side so as to surround the coil 31.

During operation, the bonding head 10′ holds an electronic element 50 using tool 24′ and brings it to a predetermined position above a substrate 51 using the above-mentioned link mechanism. Using the link mechanism, the bonding head 10 can extend the tool 24′ to move the electronic element.

The motor 30 generates force to move links 41-44.

Thereby, the tool 24′ moves substantially vertically to the stage 52 and mounts the electronic element 50 on the substrate 51.

After mounting the electronic element 50, the horn 13′ generates ultrasonic waves to bond the element 50 to the substrate 51.

As a result, the moving and bonding of the electronic element 50 can be performed by the same bonding head 10′.

While embodiments of the present invention have been described in the foregoing specification and drawings, it is to be understood that the present invention is defined by the following claims when read in light of the specification and drawings.

What is claimed is:

1. An apparatus for mounting an electronic element on a substrate, comprising:
a bonding arm that is swayable about an axis;
a horn that is fixed on said bonding arm and oscillates when an electronic element is to be bonded to a substrate;
a tool that is fixed on said horn for moving an electronic element onto a substrate and for bonding the electronic element to the substrate when said horn is oscillating; and
a motor for driving said bonding arm.

2. The apparatus of claim 1, wherein said motor is a linear motor comprising a coil and magnet.

3. The apparatus of claim 1, wherein said horn generates ultrasonic waves to bond said electronic element on said substrate.

4. The apparatus of claim 1, wherein said tool has a pipe connected to a low pressure source for holding an electronic element.

5. The apparatus of claim 1, wherein said bonding arm further comprises a link mechanism with plural links and rotating joints forming a polygon.

6. The apparatus of claim 5, wherein said link mechanism forms a parallelogram.

7. The apparatus of claim 5, wherein said tool and said link mechanism comprise a connection to a source of low pressure.

8. An apparatus for mounting an electronic element on a substrate, the apparatus comprising:
a movable bonding arm;
a motor that moves said arm;
an oscillator horn attached to said arm; and
a tool attached to said horn, said tool having an opening connected to a source of low pressure for generating a suction to hold an electronic element and having a connection to said horn for generating oscillations to bond an electronic element to a substrate.
